(19) United States
(12) Patent Application Publication
(10) Pub. No.: US 2026/0181974 A1
(43) Pub. Date: Jun. 25, 2026

(54) HIGH VOLTAGE SCHOTTKY DIODE AND CHARGE PUMP

(71) Applicant: Silicon Storage Technology, Inc., San Jose, CA (US)

(72) Inventors: Parviz Ghazavi, San Jose, CA (US); Jinho Kim, Saratoga, CA (US); Xiaozhou Qian, Shanghai (CN); Hieu Van Tran, San Jose, CA (US); Lisa Li Fang Bian, Shanghai (CN); Xiaoyan Pi, Shanghai (CN); Anh Ly, San Jose, CA (US); Kha Nguyen, Ho Chi Minh (VA); Hien Pham, Ho Chi Minh (VN); Gilles Festes, Fuveau (FR); Thibaut Pate-Cazal, Fuveau (FR); Bruno Villard, Aix en Provence PACA (FR); Xian Liu, Sunnyvale, CA (US); Nhan Do, Saratoga, CA (US)

(21) Appl. No.: 19/026,297

(22) Filed: Jan. 16, 2025

(30) Foreign Application Priority Data
Dec. 23, 2024 (CN) 202411906823.0

(51) Int. Cl. H10D 62/10; H02M 3/07; H10D 8/01; H10D 8/60; H10D 62/60

(52) U.S. Cl. CPC H10D 62/107; H02M 3/07; H10D 8/051; H10D 8/60; H10D 62/114; H10D 62/128; H10D 62/129; H10D 62/60

(57) ABSTRACT

A diode comprises a semiconductor substrate, an n-well formed in the semiconductor substrate, a p-well formed in the semiconductor substrate that is spaced apart from the n-well, a first isolation region formed in the n-well, a first electrode formed in direct contact with the n-well and formed of a metal material, a first heavily doped region formed in the n-well and having a dopant concentration greater than a dopant concentration of the n-well, a second electrode formed in direct contact with the first heavily doped region, a second isolation region formed in the semiconductor substrate and between the n-well and the p-well, a second heavily doped region formed in the p-well and having a dopant concentration greater than a dopant concentration of the p-well, and a third electrode formed in direct contact with the second heavily doped region.

### RELATED APPLICATION

This application claims the benefit of Chinese Patent Application No. 202411906823.0, filed on Dec. 23, 2024.

### FIELD OF THE INVENTION

The present disclosure relates to diodes, and specifically to Schottky diodes.

### BACKGROUND OF THE INVENTION

A diode is a two-terminal electronic component (with an anode terminal and a cathode terminal) that mainly conducts electricity in one direction. While an ideal diode will have zero resistance in one direction, and infinite resistance in the reverse direction, in practice, diodes typically have a low resistance with current flowing in one direction (anode to cathode) and a higher resistance in the reverse direction (cathode to anode). For example, placing a positive voltage on the anode (relative to the voltage potential on the cathode) will result in relatively high electrical conduction with low resistance from anode to cathode, with relatively low forward bias voltage (i.e., voltage drop across the diode). Placing a positive voltage on the cathode (relative to the voltage potential on the anode) will result in low electrical conduction with high resistance. The reverse bias voltage (voltage drop across the diode) can reach the diode's bread down voltage with very little electrical current through the diode. If the positive voltage on the cathode (relative to that on the anode) exceeds the diode's break down voltage, then there will be significant electrical conduction from cathode to anode.

There are many types of diodes. One type of diode is a Schottky diode, which can be constructed using a metal electrode bonded to an N-type semiconductor. The metal serves as the anode, and the N-type semiconductor serves as the cathode, and the metal-semiconductor junction provides the desired electrical characteristics. Schottky diodes can have relatively fast switching speeds (i.e., fast switching between on and off states), relatively low forward bias voltages, and relatively high reverse breakdown voltages (although not as high as many P/N junction diodes).

There is a need to improve the performance of Schottky diodes, namely lower turn on voltages, lower reverse bias current leakage, and higher breakdown voltages.

### BRIEF SUMMARY OF THE INVENTION

The aforementioned problems and needs are addressed by a diode that comprises a semiconductor substrate; an n-well formed in the semiconductor substrate; a p-well formed in the semiconductor substrate, wherein the p-well is spaced apart from the n-well; a first isolation region formed in the n-well; a first electrode formed in direct contact with the n-well, wherein the first electrode is formed of a metal material; a first heavily doped region formed in the n-well, wherein the first heavily doped region has a dopant concentration greater than a dopant concentration of the n-well; a second electrode formed in direct contact with the first heavily doped region; a second isolation region formed in the semiconductor substrate and between the n-well and the p-well; a second heavily doped region formed in the p-well, wherein the second heavily doped region has a dopant concentration greater than a dopant concentration of the p-well; and a third electrode formed in direct contact with the second heavily doped region.

A method of forming a diode on a semiconductor substrate, comprising: forming an n-well in the semiconductor substrate; forming a p-well in the semiconductor substrate, wherein the p-well is spaced apart from the n-well; forming a first isolation region in the n-well; forming a first electrode in direct contact with the n-well, wherein the first electrode is formed of a metal material; forming a first heavily doped region in the n-well, wherein the first heavily doped region has a dopant concentration greater than a dopant concentration of the n-well; forming a second electrode in direct contact with the first heavily doped region; forming a second isolation region in the semiconductor substrate and between the n-well and the p-well; forming a second heavily doped region in the p-well, wherein the second heavily doped region has a dopant concentration greater than a dopant concentration of the p-well; and forming a third electrode in direct contact with the second heavily doped region.

A charge pump comprises a semiconductor substrate and a plurality of pump stages each comprising a diode and a capacitor. The diode comprises an n-well formed in the semiconductor substrate, a p-well formed in the semiconductor substrate, wherein the p-well is spaced apart from the n-well, a first isolation region formed in the n-well, a first electrode formed in direct contact with the n-well, wherein the first electrode is formed of a metal material, a first heavily doped region formed in the n-well, wherein the first heavily doped region has a dopant concentration greater than a dopant concentration of the n-well, a second electrode formed in direct contact with the first heavily doped region, a second isolation region formed in the semiconductor substrate and between the n-well and the p-well, a second heavily doped region formed in the p-well, wherein the second heavily doped region has a dopant concentration greater than a dopant concentration of the p-well, and a third electrode formed in direct contact with the second heavily doped region. The capacitor has a first terminal electrically connected to the second electrode and a second terminal. For each of the pump stages, the first electrode is electrically connected to a circuit input or the second electrode of another one of the pump stages, and the second electrode is electrically connected to a circuit output or the first electrode of another one of the pump stages. A first clock signal line is electrically connected to the second terminals of a first group of the plurality of pump stages. A second clock signal line is electrically connected to the second terminals of a second group of the plurality of pump stages.

Other objects and features of the present disclosure will become apparent by a review of the specification, claims and appended figures.

### BRIEF DESCRIPTION OF THE DRAWINGS

FIG. 1 is a cross sectional view of an example of a Schottky diode.

FIG. 2A is a top view of the Schottky diode of FIG. 1.

FIG. 2B is a top view of the Schottky diode of FIG. 2A with electrodes omitted.

FIG. 3 is a cross sectional view of a second example of a Schottky diode.

FIG. 4 is a schematic diagram of a multi-stage charge pump.

FIG. 5 is a schematic diagram of a multi-stage charge pump.

### DETAILED DESCRIPTION OF THE INVENTION

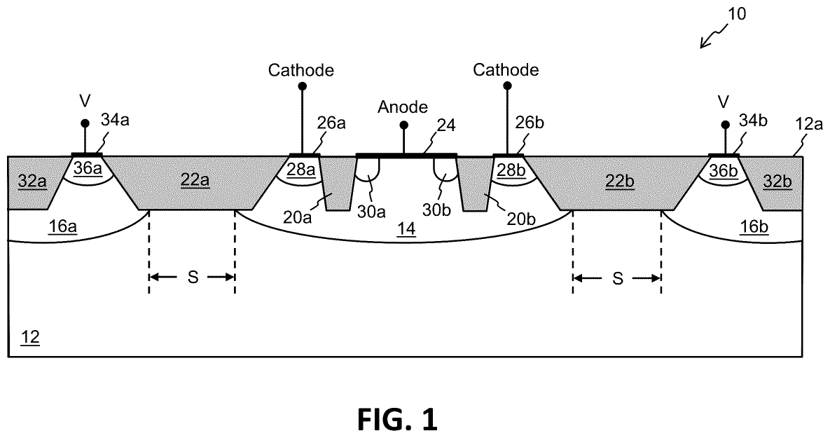

The present disclosure is directed to a Schottky diode 10 illustrated in FIG. 1. Diode 10 is formed on a semiconductor substrate 12 (e.g., silicon), which can be doped as P-type. An n-well 14 is formed in the semiconductor substrate 12. N-well 14 can be formed by introducing n-type dopants (e.g., phosphorus, arsenic, or antimony) into this region of the semiconductor substrate 12. P-wells 16a, 16b are formed in the semiconductor substrate 12, such that n-well 14 is between, and spaced apart from, p-wells 16a, 16b. P-wells 16a, 16b can be formed by introducing more p-type dopants (e.g., boron, indium, aluminum or gallium) into these regions of the semiconductor substrate 12, so that the p-type dopant concentration in the p-wells 16a, 16b is greater than the p-type dopant concentration of the surrounding p-type semiconductor substrate 12.

First isolation regions 20a, 20b and second isolation regions 22a, 22b are formed into an upper surface 12a of the semiconductor substrate 12. Isolation regions are regions of the semiconductor substrate 12 where the semiconductor material is removed and replaced with insulation material. For example, first and second isolation regions 20a/b, 22a/b can be shallow trench isolation (STI), which is a well-known technique that involves forming trenches into the upper surface of a substrate, followed by filling the trenches with insulation material, such as silicon oxide, silicon dioxide or a combination thereof (collectively referred to herein as “oxide”). As shown in FIG. 1, first isolation regions 20a, 20b are formed entirely within n-well 14. Second isolation region 22a is formed between n-well 14 and p-well 16a. Second isolation region 22b is formed between n-well 14 and p-well 16b.

A first electrode 24 (i.e., anode) is formed on the surface 12a of the semiconductor substrate 12, over n-well 14 and between the first isolation regions 20a, 20b. The first electrode 24 is formed of a metal material and is in direct contact with the n-well 14. A non-limiting example of the metal material for first electrode 24 is silicide, which is a combination of metal and silicon. The silicide can be formed by forming a layer of metal on the upper surface 12a semiconductor substrate 12, followed by an anneal process which mixes the metal and silicon together. Non-limiting examples of silicide can be nickel silicide (NiSi) and cobalt silicide (CoSi).

Second electrodes 26a, 26b (i.e., cathode) are formed on the upper surface 12a of the semiconductor substrate 12, over n-well 14. Second electrode 26a is disposed between first isolation region 20a and second isolation region 22a (i.e., first isolation region 20a is disposed between first electrode 24 and second electrode 26a), and second electrode 26b is disposed between first isolation region 20b and second isolation region 22b (i.e., first isolation region 20a is disposed between first electrode 24 and second electrode 26a). The second electrodes 26a, 26b can be made of the same material as first electrode 24.

Heavily doped regions 28a, 28b (i.e., first heavily doped regions) are formed in the n-well 14 directly under the second electrodes 26a, 26b respectively (i.e., heavily doped region 28a is disposed under second electrode 26a and between first and second isolation regions 20a, 22a, and heavily doped region 28b is disposed under second electrode 26b and between first and second isolation regions 20b, 22b). Heavily doped regions 28a, 28b can be N+ (i.e., heavily doped regions 28a, 28b have an n-type dopant concentration that is greater than the n-type dopant concentration of the surrounding n-well 14).

Heavily doped regions 30a, 30b (i.e., second heavily doped regions) can be formed in the n-well 14 directly under edge portions of first electrode 24 and extending along first isolation regions 20a, 20b. Heavily doped regions 30a, 30b can be P+ (i.e., heavily doped regions 30a, 30b have an p-type dopant concentration that is greater than the n-type dopant concentration of the n-well 14. The first electrode 24 is in direct contact with the n-well 14 between heavily doped regions 30a, 30b.

Third isolation regions 32a, 32b (of similar composition as first and second isolation regions 20a/b, 22a/b) can be formed at least partially in in p-wells 16a, 16b respectively, where third isolation region 32a is spaced from second isolation region 22a, and third isolation region 32b is spaced from second isolation region 22b.

Third electrodes 34a, 34b (i.e., for connection to a voltage source V) are formed on the upper surface 12a of the semiconductor substrate 12, over p-wells 16a, 16b respectively. Third electrode 34a is disposed between second isolation region 22a and third isolation region 32a, and third electrode 34b is disposed between second isolation region 22b and third isolation region 32b. The third electrodes 34a, 34b can be made of the same material as first electrode 24.

Heavily doped regions 36a, 36b (i.e., third heavily doped regions) are formed in the p-wells 16a, 16b directly under the third electrodes 34a, 34b respectively (i.e., heavily doped region 36a is disposed under third electrode 34a and between second and third isolation regions 22a, 32a, and heavily doped region 36b is disposed under third electrode 34b and between second and third isolation regions 22b, 32b). Heavily doped regions 36a, 36b can be P+ (i.e., heavily doped regions 36a, 36b have a p-type dopant concentration that is greater than the p-type dopant concentration of the surrounding p-wells 16a, 16b).

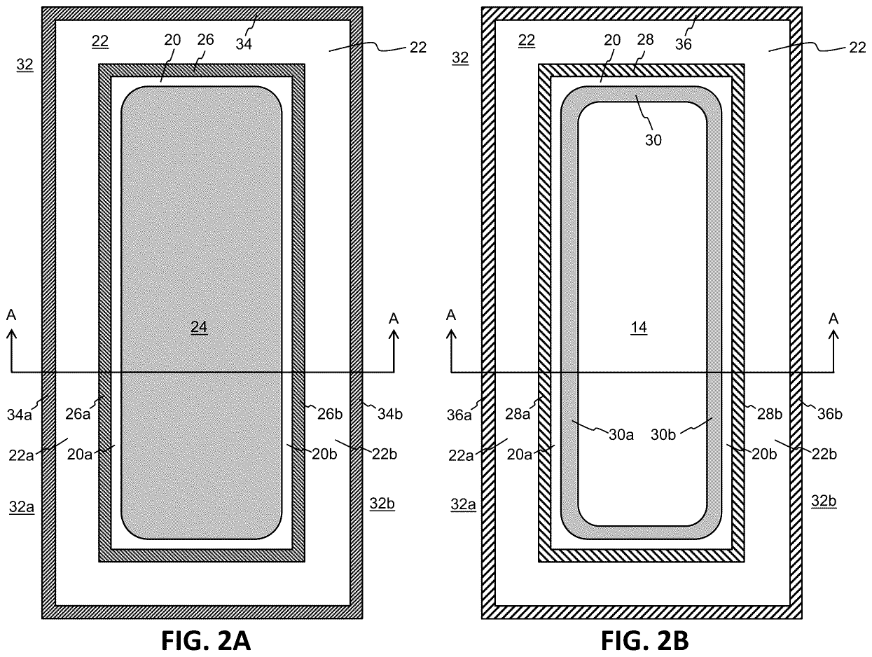

FIG. 2A is a top view of the upper surface 12a of the semiconductor substrate 12, where FIG. 1 is a cross sectional view along line A-A in FIG. 2A. FIG. 2B is the same top view as FIG. 2A, except with first electrode 24, second electrodes 26a, 26b and third electrodes 34a, 34b omitted. The first electrode 24 can have a rectangular shape. The first isolation regions 20a, 20b can be a continuous first isolation region 20 that encircles first electrode 24 (i.e., as viewed from above the upper surface 12a). The second electrodes 26a, 26b can be a continuous second electrode 26 that encircles first isolation region 20. Second isolation regions 22a, 22b can be a continuous second isolation region 22 that encircles first isolation region 20. Third electrodes 34a, 34b can be a continuous third electrode 34 that encircles second isolation region 22. Accordingly, heavily doped regions 28a, 28b can be a continuous heavily doped region 28 extending underneath second electrode 26 and encircling first isolation region 20, heavily doped regions 36a, 36b can be a continuous heavily doped region 36 extending underneath third electrode 34 and encircling second isolation region 22, heavily doped regions 30a, 30b can be a continuous heavily doped region 30 extending under the first electrode 24 and along first isolation region 20, and third isolation regions 32a, 32b can be a continuous third isolation region 32 encircling heavily doped region 36.

The first electrode 24 (made of a metal material) is in direct contact with the relatively low doped n-well 14 portion of the semiconductor substrate 12, forming a metal-semiconductor junction with a Schottky barrier that is conductive in the forward bias direction (i.e., current flowing in the forward direction when a positive voltage is applied to first electrode 24 relative to n-well 14) with a barrier height of approximately 0.5 volts. The Schottky barrier is generally not conductive (i.e., high electrical resistance) in the reverse bias direction (i.e., where there is a positive voltage on the n-well 14 relative to the first electrode 24). In contrast, the second electrodes 26a, 26b (also made of metal material) are in direct contact with the heavily doped regions 28a, 28b of semiconductor substrate 12. The high dopant levels of heavily doped regions 28a, 28b effectively changes the work function of the n-type semiconductor to be closer to the work function of the metal silicide (which is fixed). The end result is that the metal-semiconductor junction at the second electrodes 26a, 26b is conductive in both directions without a significant Schottky barrier to impede current flow in either direction.

In operation, when a positive voltage is applied to the first electrode 24 (relative to the voltage applied to the second electrodes 26a, 26b), electrical current flows in the forward direction with low resistance and a low forward bias voltage from the first electrode 24, through the n-well 14 including under first isolation regions 20a, 20b, to second electrodes 26a, 26b. The turn-on voltage (i.e., the voltage that turns current flow on in the forward direction) can be as low as approximately 0.5 V as one example. In contrast, when a positive voltage is applied to the second electrodes 26a, 26b (relative to the voltage applied to the first electrode 24), there is high resistance that suppresses current flow in the reverse direction due to the Schottky barrier at the first electrode 24. The break-down voltage (i.e., the voltage that turns current flow on in the reverse direction despite the high Schottky barrier) can be greater than 16 V as one example.

Also during operation, applying a low, ground or negative voltage V to the third electrodes 34a, 34b captures minority carriers leaking through the substrate 12 which are conducted out through third electrodes 34a, 34b. Effective minority carrier capture is achieved by having the p-wells 16a, 16b spaced from the n-well 14 by a spacing S. Spacing S allows minority carrier capture from the semiconductor material of the semiconductor substrate 12 under the second isolation regions 22a, 22b. The third electrodes 34a, 34b (also made of metal material) are in direct contact with the heavily doped regions 36a, 36b of semiconductor substrate 12. The heavily doped regions 36a, 36b serve change the work function of the p-type doped semiconductor material to be closer to the work function of the metal silicide (which is fixed). The end result is that the metal-semiconductor junction at the third electrodes 34a, 34b is conductive in both directions without a significant Schottky barrier to impede current flow in either direction.

The diode 10 has many advantages. Diode 10 can have a low turn-on voltage, e.g. approximately 0.5 V at room temperature. The reverse bias breakdown voltage can exceed 9-10 V, with very little leakage current below the reverse bias breakdown. The transition from heavily doped regions 28a, 28b to n-well 14 between first isolation regions 20a, 20b and second isolation regions 22a, 22b results in low reverse saturation current leakage. The inclusion of heavily doped regions 30a, 30b under the first electrode 24 is optional, but has been found to reduce leakage current by as much as a factor of four to six at room temperature and by a factor of two to three at high temperature, and a high ratio (e.g., >20) between the on current (in the forward direction) and off current (in the reverse direction), with no appreciable penalty on anode capacitance. The separation S between n-well 14 and p-wells 16a, 16b (by the semiconductor substrate material under second isolation regions 22a, 22b) contributes to the high break down voltage. The configuration of diode 10 as a whole provides low reverse direction current leakage, and a fast switching action between forward bias (conductance on) and reverse bias (conductance off) and vice versa. The area occupied by the first electrode 24 can be made relatively small, thereby providing low parasitic capacitance with little or no degradation of the forward direction turn-on voltage.

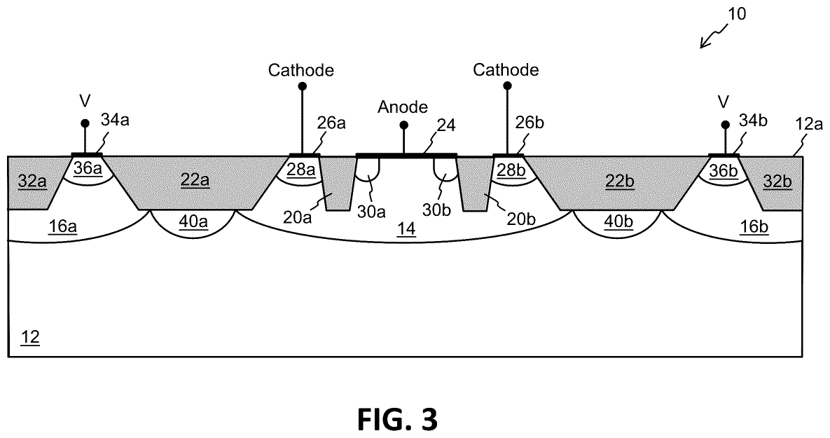

FIG. 3 illustrates another example, which is similar to the example of FIG. 1, but n-wells 40a, 40b are added under second isolation regions 22a, 22b, and between n-well 14 and p-wells 16a, 16b. N-wells 40a, 40b can have an n-type dopant concentration less than that of n-well 14 to provide a higher reverse breakdown voltage. It has been discovered that adding n-wells 40a, 40b can increase the overall breakdown voltage.

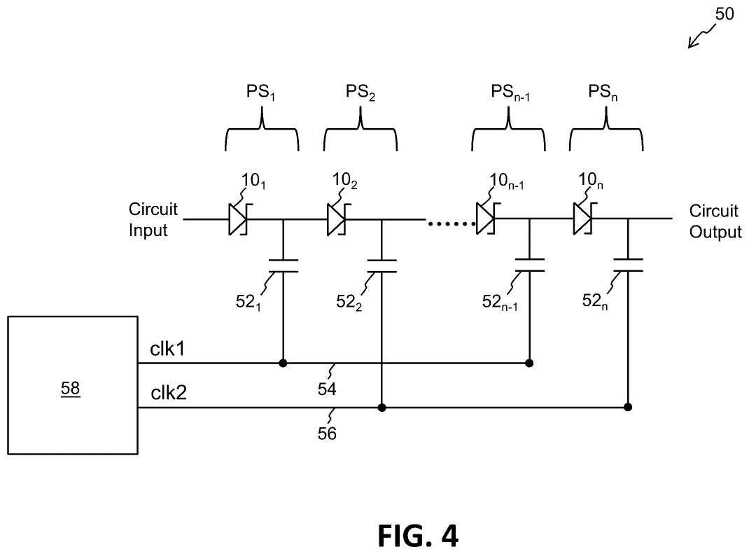

FIG. 4 illustrates an example application for diode 10. Specifically, a multi-stage charge pump 50 for pumping up an input voltage can utilize a plurality of diodes 10 connected in series. The multi-stage charge pump 50 includes multiple pump stages PS₁-PSₙ (where n is greater than or equal to 4). Each pump stage PS includes a diode 10 (of the type described above with respect to FIGS. 1-3), and a capacitor 52. Each diode 10 has an input terminal (i.e., its first electrode 24), and an output terminal (i.e., its second electrode 26). The circuit input of the multi-stage charge pump 50 is placed on the first electrode 24 of diode 10₁, where the second electrode 26 of diode 10₁ is electrically connected to first electrode 24 of diode 10₂, and the second electrode 26 of diode 10₂ is electrically connected to the first electrode 24 of diode 10₃, and so on. The second electrode 26 of diode 10ₙ provides the circuit output of the multi-stage charge pump 50. Therefore, for each pump stage PS, the first electrode 24 is electrically connected to the second electrode 26 of the preceding pump stage PS, except for the first pump stage PS₁ where the first electrode 24 is connected to the circuit input. Similarly, for each pump stage PS, the second electrode 26 is electrically connected to the first electrode 24 of the succeeding pump stage PS, except for the last pump stage PSₙ where the second electrode 26 is connected to the circuit output.

The capacitor 52 for each pump stage PS includes a first terminal electrically connected to the second electrode 26 of the respective diode 10 and a second terminal electrically connected to either a first clock signal line 54 or a second clock signal line 56. Specifically, for the odd numbered pump stages PS₁ . . . PSₙ₋₁ (i.e., a first group of the pump stages PS), the second terminals of respective capacitors 52₁ . . . 52ₙ₋₁ are connected to first clock signal line 54; for the even numbered pump stages PS₂ . . . PSₙ (i.e., a second group of the pump stages PS), the second terminals of respective capacitors 52₂ . . . 52ₙ are connected to second clock signal line 56; where the odd numbered pump stages PS₁ . . . PSₙ₋₁ (i.e., the first group of the pump stages PS) alternate with the even numbered pump stages PS₂ . . . PSₙ (i.e., the second group of the pump stages PS).

A clock signal source circuitry 58 is connected to the first and second clock signal lines 54, 56 to provide a first clock signal clk1 on first clock signal line 54 and a second clock signal clk2 on second clock signal line 56. The clock signal source circuitry 58 can generate first and second clock signals clk1 and clk2 on chip, or can receive first and second clock signals ckk1 and clk2 from an off chip source. First clock signal clk1 is the inverse of the second clock signal (i.e., when first clock signal clk1 is low, second clock signal clk2 is high, and vice versa).

The multi-stage charge pump 50 has many advantages. Only two clock signals are used to operate the multi-stage charge pump 50. The clock signals can be fast due to the quick response (i.e., switch time) of the Schottky diodes 10. The size of multi-stage charge pump 50 can be significantly smaller than conventional pump designs, as can be the power consumption. The pump efficiency is higher than conventional pump designs, so that a lower starting voltage can be used. As a non-limiting example, the multi-stage charge pump 50 having twenty pump stages (i.e., n=20), using first and second clock signals clk1, clk2 each with a clock frequency of 10 ns, and an input voltage of 1.6 V, can output a voltage of 12 V with a power consumption of 0.8 mA, and can occupy a total area of 0.03 square millimeters. As another non-limiting example, the multi-stage charge pump 50 having twenty pump stages (i.e., n=20), using first and second clock signals clk1, clk2 each with a clock frequency of 5 ns, and an input voltage of 1.6 V, can output a voltage of 12 V with a power consumption of 1.08 mA, and can occupy a total area of 0.016 square millimeters.

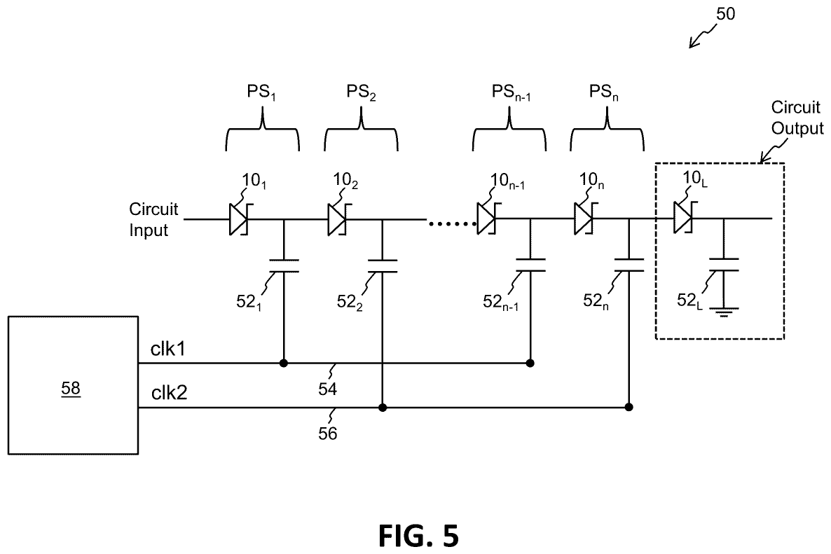

FIG. 5 illustrates another example of multi-stage charge pump 50, which is the same as that shown in FIG. 4 except the circuit output includes a load diode 10_{L} and a load capacitor 52_{L}. The load diode 10_{L} can be of the type described above with respect to FIGS. 1-3 (i.e., with the same elements as described above, where each element can be separately referred to with a preceding “load” for clarity, such as load n-well 14, first load isolation region 20, second load isolation region 22, first load electrode 24, second load electrode 26, and so on for all the elements of the diode 10 described above with respect to FIGS. 1, 2A, 2B and 3 being the elements of load diode 10_{L}). The second electrode 26 of diode 10ₙ is electrically connected to first load electrode 24 of load diode 10_{L}. Load capacitor 52_{L} includes a first load terminal electrically connected to the second load electrode 26 of the load diode 10_{L} and a second load terminal electrically connected to a voltage source such as ground. The advantage of including the load diode 10_{L} and the load capacitor 52_{L} as part of the circuit output is to provide the charge pump output to a node with a loading capacitance.

It should be noted that while FIGS. 2A and 2B show continuous elements encircling the first electrode 24 (i.e., continuous first isolation region 20 encircling first electrode 24, continuous second electrode 26 encircling first isolation region 20, continuous second isolation region 22 encircling first isolation region 20 and second electrode 26, continuous third electrode 34 encircling second isolation region 22, and so on), these elements need not be continuous whereby each of these elements could be formed as two or more such elements to form a single diode 10.

It is to be understood that the present disclosure is not limited to the example(s) described above and illustrated herein, but encompasses any and all variations falling within the scope of any claims. For example, references to the present disclosure or invention or examples herein are not intended to limit the scope of any claim or claim term, but instead merely make reference to one or more features that may be covered by one or more claims. Materials, processes and numerical examples described above are exemplary only, and should not be deemed to limit the claims. Single layers of material could be formed as multiple layers of such or similar materials, and vice versa. The terms “forming” and “formed” as used herein shall include material deposition, material growth, or any other technique in providing the material as disclosed or claimed. The claims are comprising claims unless otherwise stated, and therefore “each” of a plurality of elements having a limitation does not preclude the inclusion of additional such elements lacking the limitation unless otherwise specifically claimed. Finally, it should be noted that reference herein to circuitry, or a module of circuitry, or the like, to perform or configured to perform an operation refers to the physical structure of the circuit (i.e., the capabilities of the circuitry as dictated by its structure), and does not refer to any method or actual use of the circuitry.

What is claimed is:

1. A diode, comprising:
a semiconductor substrate;
an n-well formed in the semiconductor substrate;
a p-well formed in the semiconductor substrate, wherein the p-well is spaced apart from the n-well;
a first isolation region formed in the n-well;
a first electrode formed in direct contact with the n-well, wherein the first electrode is formed of a metal material;
a first heavily doped region formed in the n-well, wherein the first heavily doped region has a dopant concentration greater than a dopant concentration of the n-well;
a second electrode formed in direct contact with the first heavily doped region;
a second isolation region formed in the semiconductor substrate and between the n-well and the p-well;
a second heavily doped region formed in the p-well, wherein the second heavily doped region has a dopant concentration greater than a dopant concentration of the p-well; and
a third electrode formed in direct contact with the second heavily doped region.

2. The diode of claim 1, wherein the first heavily doped region comprises an n-type dopant.

3. The diode of claim 1, wherein the second heavily doped region comprises a p-type dopant.

4. The diode of claim 1, comprising:
a third heavily doped region formed under and in direct contact with the first electrode, wherein the third heavily doped region has a dopant concentration greater than a dopant concentration of the n-well.

5. The diode of claim 4, wherein the third heavily doped region comprises a p-type dopant.

6. The diode of claim 4, wherein the third heavily doped region extends along the first isolation region.

7. The diode of claim 1, wherein:
the first isolation region comprises an oxide; and
the second isolation region comprises an oxide.

8. The diode of claim 1, wherein the semiconductor substrate comprises p-type dopant.

9. The diode of claim 1, wherein:
the first isolation region encircles the first electrode;
the second electrode encircles the first isolation region;
the second isolation region encircles the second electrode; and
the third electrode encircles the second isolation region.

10. The diode of claim 9, wherein:
the first heavily doped region encircles the first isolation region; and
the second heavily doped region encircles the second isolation region.

11. The diode of claim 1, comprising:
a second n-well formed under the first isolation region and between the n-well and the p-well.

12. A method of forming a diode on a semiconductor substrate, comprising:
forming an n-well in the semiconductor substrate;
forming a p-well in the semiconductor substrate, wherein the p-well is spaced apart from the n-well;
forming a first isolation region in the n-well;
forming a first electrode in direct contact with the n-well, wherein the first electrode is formed of a metal material;
forming a first heavily doped region in the n-well, wherein the first heavily doped region has a dopant concentration greater than a dopant concentration of the n-well;
forming a second electrode in direct contact with the first heavily doped region;
forming a second isolation region in the semiconductor substrate and between the n-well and the p-well;
forming a second heavily doped region in the p-well, wherein the second heavily doped region has a dopant concentration greater than a dopant concentration of the p-well; and
forming a third electrode in direct contact with the second heavily doped region.

13. The method of claim 12, wherein the first heavily doped region comprises an n-type dopant and the second heavily doped region comprises a p-type dopant.

14. The method of claim 12, comprising:
forming a third heavily doped region under and in direct contact with the first electrode, wherein the third heavily doped region has a dopant concentration greater than a dopant concentration of the n-well.

15. The method of claim 12, wherein:
the first isolation region encircles the first electrode;
the second electrode encircles the first isolation region;
the second isolation region encircles the second electrode; and
the third electrode encircles the second isolation region.

16. The method of claim 15, wherein:
the first heavily doped region encircles the first isolation region; and
the second heavily doped region encircles the second isolation region.

17. The method of claim 12, further comprising:
forming a second n-well under the first isolation region and between the n-well and the p-well.

18. A charge pump, comprising:
a semiconductor substrate;
a plurality of pump stages, wherein each pump stage comprises:
a diode comprising:
an n-well formed in the semiconductor substrate,
a p-well formed in the semiconductor substrate, wherein the p-well is spaced apart from the n-well,
a first isolation region formed in the n-well,
a first electrode formed in direct contact with the n-well, wherein the first electrode is formed of a metal material,
a first heavily doped region formed in the n-well, wherein the first heavily doped region has a dopant concentration greater than a dopant concentration of the n-well,
a second electrode formed in direct contact with the first heavily doped region,
a second isolation region formed in the semiconductor substrate and between the n-well and the p-well,
a second heavily doped region formed in the p-well, wherein the second heavily doped region has a dopant concentration greater than a dopant concentration of the p-well, and
a third electrode formed in direct contact with the second heavily doped region; and
a capacitor having a first terminal electrically connected to the second electrode and a second terminal;
wherein for each of the pump stages:
the first electrode is electrically connected to a circuit input or the second electrode of another one of the pump stages, and
the second electrode is electrically connected to a circuit output or the first electrode of another one of the pump stages;
a first clock signal line electrically connected to the second terminals of a first group of the plurality of pump stages; and
a second clock signal line electrically connected to the second terminals of a second group of the plurality of pump stages.

19. The charge pump of claim 18, comprising:
a clock signal source circuitry to provide a first clock signal to the first clock signal line and a second clock signal to the second clock signal line, wherein the first clock signal is an inverse of the second clock signal.

20. The charge pump of claim 18, wherein the first group of the plurality of pump stages alternate with the second group of the plurality of pump stages.

21. The charge pump of claim 18, comprising:
a load diode comprising:
a load n-well formed in the semiconductor substrate,
a load p-well formed in the semiconductor substrate, wherein the load p-well is spaced apart from the load n-well,
a first load isolation region formed in the load n-well,
a first load electrode formed in direct contact with the load n-well, wherein the first load electrode is formed of a metal material,
a first load heavily doped region formed in the load n-well, wherein the first load heavily doped region has a dopant concentration greater than a dopant concentration of the load n-well,
a second load electrode formed in direct contact with the first load heavily doped region,
a second load isolation region formed in the semiconductor substrate and between the load n-well and the load p-well,
a second load heavily doped region formed in the load p-well, wherein the second load heavily doped region has a dopant concentration greater than a dopant concentration of the load p-well, and
a third load electrode formed in direct contact with the second load heavily doped region; and
a load capacitor having a first load terminal electrically connected to the second load electrode and a second load terminal electrically connected to a voltage source.

22. The charge pump of claim 21, wherein the voltage source is ground.
